(19) United States
(12) Patent Application Publication
(10) Pub. No.: US 2006/0017161 A1
(43) Pub. Date: Jan. 26, 2006

(54) Semiconductor package having protective layer for re-routing lines and method of manufacturing the same

(76) Inventors: Jae-Sik Chung, Hwaseong-si (KR); Se-Young Jeong, Seoul (KR); Dong-Hyeon Jang, Suwon-si (KR)

Correspondence Address: HARNESS, DICKEY & PIERCE, P.L.C., P.O. BOX 8910, RESTON, VA, 20195, US

(21) Appl. No.: 11/186,964

(22) Filed: Jul. 22, 2005

(30) Foreign Application Priority Data
Jul. 22, 2004 (KR) 2004-57245

(51) Int. Cl. H01L 21/44; H01L 23/48

(52) U.S. Cl. 257/737; 438/613; 257/738; 257/750; 257/774; 438/629; 257/784; 438/617

(57) ABSTRACT

An apparatus and method for manufacturing a semiconductor package are disclosed. The apparatus may include at least a semiconductor chip having input/output (I/O) pads arranged on a surface thereof, a first dielectric layer formed on the surface of the semiconductor chip which may expose the I/O pads, a seed metal layer selectively formed on the first dielectric layer and the I/O pads, re-routing lines formed on the seed metal layer and electrically coupled to the I/O pads, a protective coating layer on side surfaces and an upper surface of each re-routing line, a second dielectric layer formed on the first dielectric layer which may cover the re-routing lines surrounded with the protective coating layer, and solder balls formed on the respective pads and electrically coupled to the re-routing lines.

### CROSS REFERENCE TO RELATED APPLICATIONS

This U.S. non-provisional application claims priority under 35 U.S.C. §119 to Korean Patent Application No. 2004-57245, filed on Jul. 22, 2004, in the Korean Intellectual Property Office, the contents of which are incorporated by reference herein in their entirety.

### BACKGROUND OF THE INVENTION

1. Field of the Invention

Exemplary embodiments of the present invention relate generally to an electronic packaging technology.

2. Description of the Related Art

Electronic products are evolving toward lighter weight, smaller size, higher speed, more functionality, higher performance, better reliability, and/or more cost-effective fabrication. As a result, package assembly technology may become more important. A wafer level package (WLP) may be one example of an advanced modern package. The WLP may allow simultaneous fabrication of chip-sized packages in the wafer state prior to chip separation.

FIG. 1 illustrates, in a cross-sectional view, a structure of a conventional WLP 10. Referring to FIG. 1, input/output (I/O) pads 12 of a semiconductor device 11, such as, an integrated circuit (IC) chip may be electrically connected to solder balls 18 (i.e., package terminals), via re-routing lines 16 provided on the IC chip 11.

A passivation layer 13 may cover a top surface of the IC chip 11 which may expose the I/O pads 12. A first dielectric layer 14 may be formed on the passivation layer 13 which may also expose the I/O pads 12. A seed metal layer 15 and the re-routing lines 16 may be sequentially formed on the I/O pads 12 as well as on the first dielectric layer 14. The re-routing lines 16 may be covered with a second dielectric layer 17 provided over the first dielectric layer 14. Parts of the second dielectric layer 17 may be removed to partly expose the re-routing lines 16 for the solder balls 18.

Conventionally, the seed metal layer 15 may be composed of two or three layers, which may act as an adhesive layer, a diffusion barrier layer, and/or a plate electrode layer when the re-routing lines 16 are formed on the first dielectric layer 14. FIGS. 2A and 2B illustrate a process for forming the seed metal layer 15. FIG. 1 illustrates a cross-section taken along the length of the re-routing lines 16, and FIGS. 2A and 2B illustrate a cross-section taken along the width of the re-routing lines 16.

As shown in FIG. 2A, the seed metal layer 15 may be wholly deposited on the first dielectric layer 14, and then the re-routing lines 16 may be formed on the seed metal layer 15 by using, for example, an electroplating technique. As shown in FIG. 2B, the seed metal layer 15 may then selectively be removed by using, for example, a wet etching technique. During the wet etching, the re-routing lines 16 may act as an etch mask.

Further, the re-routing lines 16 may also be affected by an etching solution while the seed metal layer 15 may be wet-etched. However, this may produce, for example, over-etching of sidewalls of the re-routing lines 16. Such sidewall over-etching of the re-routing lines 16 may deepen when the seed metal layer 15 is made of the same material (e.g., metal) as the re-routing lines 16. In addition, the smaller the width and the space between the re-routing lines 16, the deeper the sidewall over-etching of the re-routing lines 16 may become.

FIG. 3 illustrates undesirable results of a conventional WLP sidewall over-etching of the re-routing lines 16. As shown in FIG. 3, the deep sidewall over-etching may cause undercutting of the re-routing lines 16. In other words, such undercutting may cause the re-routing lines 16 to produce a falling down effect (as indicated by reference numeral 21) and/or lifting effect (as indicated by reference numeral 22) of the re-routing lines 16.

### SUMMARY OF THE INVENTION

Exemplary embodiments of the present invention may provide a semiconductor package including at least a semiconductor chip having input/output (I/O) pads arranged on a surface thereof, a first dielectric layer formed on the surface of the semiconductor chip, exposing the I/O pads, a seed metal layer formed on the first dielectric layer and the I/O pads, re-routing lines formed on the seed metal layer and electrically coupled to the I/O pads, a protective coating layer on side surfaces and an upper surface of each re-routing line, a second dielectric layer formed on the first dielectric layer which may cover the re-routing lines surrounded with the protective coating layer, and may expose part of the re-routing lines defined as pads, and solder balls formed on the respective pads and electrically coupled to the re-routing lines.

In other exemplary embodiments, the protective coating layer may be made of a material different from that of the seed metal layer.

In yet other exemplary embodiments, the protective coating layer may be made of metal selected from at least one of nickel (Ni), gold (Au) and chromium (Cr).

In other exemplary embodiments, the protective coating layer may be made of metal selected from at least one of nickel (Ni), gold (Au) and chromium (Cr).

Exemplary embodiments of the present invention may provide a semiconductor package including at least a semiconductor chip having input/output (I/O) pads arranged on a surface thereof, a first layer formed on the surface of the semiconductor chip, exposing the I/O pads, connection lines formed on the first layer and electrically coupled to the I/O pads, a protective coating layer on side surfaces and an upper surface of each connecting line, and a second layer formed on the first layer which may cover the connection lines surrounded with the protective coating layer.

In other exemplary embodiments, the I/O pads may be arranged in at least one row at a central region of the semiconductor chip.

In yet other exemplary embodiments, the I/O pads may be arranged in at least one row at a peripheral region of the semiconductor chip.

In other exemplary embodiments, the first layer may be formed on a passivation layer.

In other exemplary embodiments, the first layer may be made from a polymeric material.

In yet other exemplary embodiments, the polymeric material may be at least one of a polyimide, an epoxy and a benzo-cyclo-butene.

In other exemplary embodiments, the second layer may expose part of the connection lines.

In other exemplary embodiments, the second layer may be made from a polymeric material.

In yet other exemplary embodiments, the polymeric material may be at least one of a polyimide, an epoxy and a benzo-cyclo-butene.

In other exemplary embodiments, apparatus may include a seed metal layer wherein the seed metal layer may be formed on the first layer and the I/O pads.

In other exemplary embodiments, the connection lines may be provided on the seed metal layer.

In other exemplary embodiments, the seed metal layer may be composed of an adhesive layer and a diffusion barrier layer.

In yet other exemplary embodiments, the seed metal layer may be composed of an adhesive layer, a diffusion barrier layer and a plating electrode layer.

In other exemplary embodiments, the seed metal layer may be made from at least one metal.

In yet other exemplary embodiments, the at least one metal may be at least one of titanium and copper (Ti/Cu), chromium and copper (Cr/Cu), chromium and nickel (Cr/Ni), chromium and vanadium (Cr/Ni/Au), titanium, copper and nickel (Ti/Cu/Ni), and chromium, nickel and gold (Cr/Ni/Au).

In other exemplary embodiments, the seed metal layer may be covered with a photoresist pattern.

In other exemplary embodiments, the photoresist pattern may include plurality of openings to expose selected parts of the seed metal layer.

In other exemplary embodiments, the photoresist pattern may be formed from a positive photoresist material.

In yet other exemplary embodiments, the photoresist pattern may be formed from a negative photoresist material.

In other exemplary embodiments, the apparatus may include solder balls formed on ball pads of the second layer.

In yet other exemplary embodiments, the solder balls may be provided as package terminals on the respective ball pads.

In other exemplary embodiments, an under bump metal may be provided under the solder balls.

In other exemplary embodiments, the connection lines may be made of copper.

Exemplary embodiments of the present invention may include a method of manufacturing having forming a first dielectric layer on a semiconductor chip which includes input/output (I/O) pads arranged on a top surface thereof, the first dielectric layer exposing the I/O pads, forming a seed metal layer on the first dielectric layer and the I/O pads, forming re-routing lines on the seed metal layer, forming a protective coating layer on side surfaces and an upper surface of each re-routing line, etching the seed metal layer using the re-routing lines coated with the protective coating layer as an etch mask, to remove exposed parts of the seed metal layer, forming a second dielectric layer on the first dielectric layer so as to cover the re-routing lines coated with the protective coating layer and to expose parts of the re-routing lines defined as pads, and forming solder balls on the respective pads.

In other exemplary embodiments, the etching of the seed metal layer may be performed by wet etching.

In other exemplary embodiments, the forming of the re-routing lines may include forming a photoresist pattern having openings in the seed metal layer, and selectively depositing a metal layer on the seed metal layer within the openings.

In other exemplary embodiments, the photoresist pattern may be formed from positive photoresist material.

In yet other exemplary embodiments, the photoresist pattern may be formed from negative photoresist material.

In other exemplary embodiments, the forming of the protective coating layer may include forming a space between the photoresist pattern and the re-routing lines using a second exposure and development process, and selectively depositing the protective coating layer on the re-routing lines and in the space.

In other exemplary embodiments, the forming of the protective coating layer may include stripping the photoresist pattern, forming a second photoresist pattern having a space between the second photoresist pattern and the re-routing lines, and selectively depositing the protective coating layer on the re-routing lines and in the space.

In other exemplary embodiments, the forming of the protective coating layer may be performed by electroplating.

Exemplary embodiments of the present invention may include a method of manufacturing having forming a first layer on a semiconductor chip which may include input/output (I/O) pads arranged on a surface thereof, the first layer exposes the I/O pads, forming connection lines on the first layer, forming a protective coating layer on side surfaces and an upper surface of each connection line, and forming a second layer over the first layer so as to cover the connection lines coated with the protective coating layer.

In other exemplary embodiments, the forming the first layer may be formed by spin coating.

In other exemplary embodiments, the first layer exposing the I/O pads may be performed by photolithography.

Exemplary embodiments of the present invention may provide a wafer level package having a protective coating layer for re-routing lines.

### BRIEF DESCRIPTION OF THE DRAWINGS

FIG. 1 is a cross-sectional view illustrating a conventional semiconductor package.

FIGS. 2A and 2B are cross-sectional views illustrating processes of forming a seed metal layer in the conventional semiconductor package.

FIG. 3 is a cross-sectional view showing undesirable results of sidewall over-etching of rerouting lines in the conventional semiconductor package.

FIG. 4 is a partial perspective view illustrating a semiconductor package in accordance with an exemplary embodiment of the present invention.

FIG. 5 is a cross-sectional view taken along the line V-V of FIG. 4.

FIG. 6 is a cross-sectional view taken along the line VI-VI of FIG. 4.

FIGS. 7A to 7H are cross-sectional views sequentially illustrating a method of manufacturing a semiconductor package in accordance with an exemplary embodiment of the present invention.

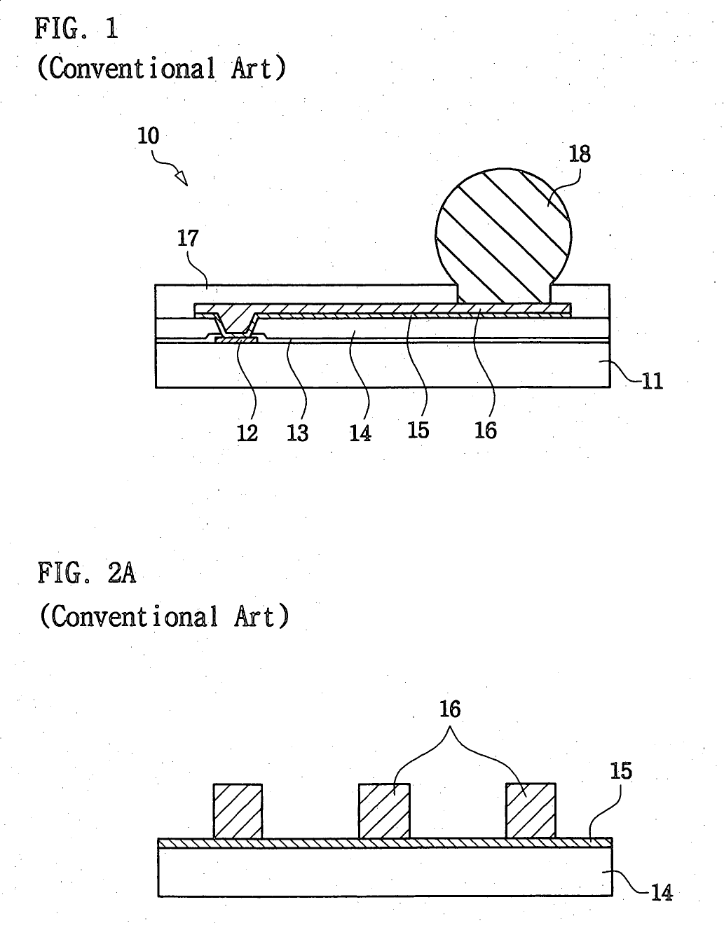

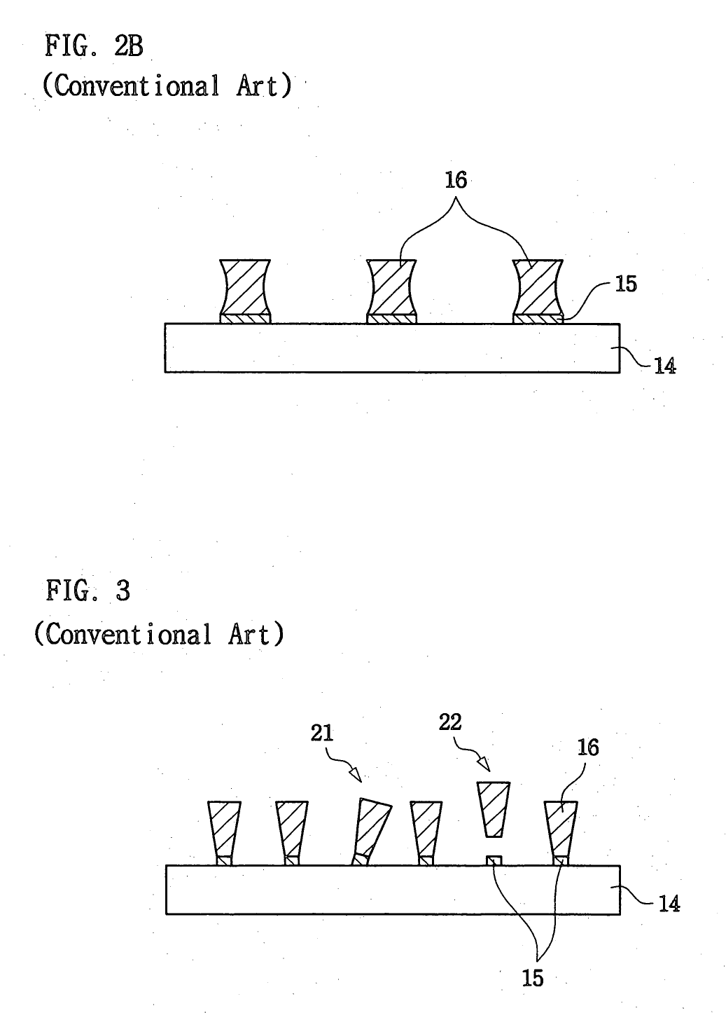

### DETAILED DESCRIPTION OF EXEMPLARY EMBODIMENTS

Exemplary, non-limiting embodiments of the present invention will now be described more fully hereinafter with reference to the accompanying drawings. This invention may, however, be embodied in many different forms and should not be construed as limited to the exemplary embodiments set forth herein. Rather, the disclosed embodiments are provided so that this disclosure will be thorough and complete, and will fully convey the scope of the invention to those skilled in the art. The principles and feature of this invention may be employed in varied and numerous embodiments without departing from the scope of the invention.

It should be noted that these figures are intended to illustrate the general characteristics of methods and devices of exemplary embodiments of this invention, for the purpose of the description of such exemplary embodiments herein. These drawings are not, however, to scale and may not precisely reflect the characteristics of any given embodiment, and should not be interpreted as defining or limiting the range of values or properties of exemplary embodiments within the scope of this invention. Rather, for simplicity and clarity of illustration, the dimensions of some of the elements are exaggerated relative to other elements.

In particular, the relative thicknesses and positioning of layers or regions may be reduced or exaggerated for clarity. Further, a layer is considered as being formed “on” another layer or a substrate when formed either directly on the referenced layer or the substrate or formed on other layers or patterns overlaying the referenced layer. Further, it will be understood that when a layer is referred to as being “on” or “formed over” another layer or substrate, the layer may be directly on the other layer or substrate, or intervening layer(s) may also be present.

Further, well-known structures and processes are not described or illustrated in detail to avoid obscuring the present invention. Like reference numerals are used for like and corresponding parts of the various drawings.

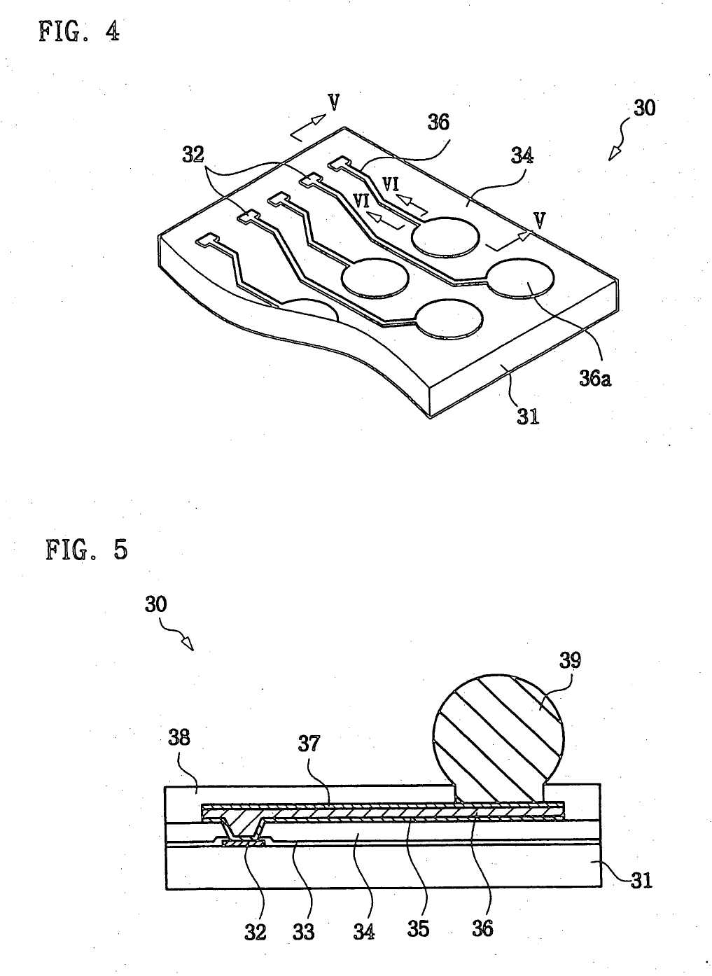

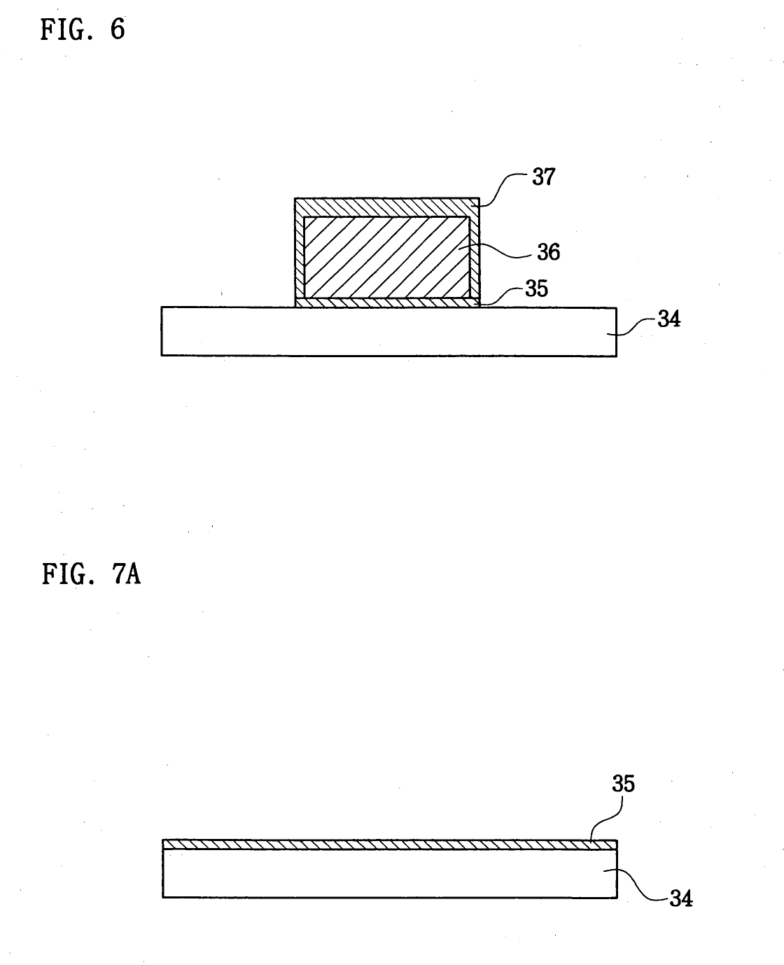

FIG. 4 is a partial perspective view illustrating a wafer level package (WLP) 30 in accordance with an exemplary embodiment of the present invention. FIG. 5 is a cross-sectional view taken along the line V-V of FIG. 4, and FIG. 6 is a cross-sectional view taken along the line VI-VI of FIG. 4. Particularly, FIG. 5 illustrates a cross-section taken along the length of re-routing lines 36, and FIG. 6 shows a cross-section taken along the width of the re-routing lines 36.

Referring to FIGS. 4 to 6, all elements of the WLP 30 may be formed on a semiconductor device, such as an integrated circuit (IC) chip 31 in the wafer state. It should be appreciated that the structure and the shape of the WLP 30 and relative position of the elements in the WLP 30, shown in FIGS. 4 to 6, are considered exemplary embodiments only and not to be considered as a limitation of the present invention. In addition, the structure shown in FIGS. 4 to 6 may correspond to parts of the individual WLP 30.

The IC chip 31 may have a number of input/output (I/O) pads 32 that may be formed through a general wafer fabrication process. The I/O pads 32 may be arranged in a row at a central region or a peripheral region of a top surface of the IC chip 31. It should be appreciated that other arrangement of the I/O pads may be employed. The top surface of the IC chip 31 may be covered with a passivation layer 33 to protect the chip internal circuits, except for the region where the I/O pads 32 are formed. It should be appreciated that the passivation layer may be generally described as a layer that is, for example, coated to protect against contamination and/or increase electrical stability.

A first dielectric layer 34 may be provided on the passivation layer 33. The first dielectric layer 34 may not only provide electrical isolation, but may also reduce and/or relieve thermally induced stress. The first dielectric layer 34 may be made of polymeric material, such as, but not limited to polyimide, epoxy, and benzo-cyclo-butene (BCB).

A seed metal layer 35 may be selectively provided on both the first dielectric layer 34 and the I/O pads 32. Re-routing lines 36 may be provided on the seed metal layer 35. The seed metal layer 35 may be composed of two or more layers, which may act as an adhesive layer, a diffusion barrier layer, and/or a plating electrode layer, when the re-routing lines 36 are formed on the first dielectric layer 34. The seed metal layer 35 may be composed of various metals, such as titanium and copper (Ti/Cu), chromium and copper (Cr/Cu), chromium and nickel (Cr/Ni), chromium and vanadium (Cr/V), titanium, copper and nickel (Ti/Cu/Ni), or chromium, nickel and gold (Cr/Ni/Au). It should be appreciated that other combination of the above metals may be employed. It should further be appreciated that other metals beside the one mentioned above may be employed. Each re-routing line 36 may connect the I/O pad 32 and a solder ball 39, forming a specific pattern and may act as a path for transmitting electric signals and power. It should be appreciated that the re-routing lines may be generally defined as a way to connect, link, join, tie, attach and/or bond the I/O pads to the solder balls. The re-routing lines 36 may be made of metal, such as, but not limited to, copper (Cu), which may have good electric conductivity.

A protective coating layer 37 may be provided on side surfaces as well as an upper surface of each re-routing line 36, as best shown in FIG. 6. The protective coating layer 37 may protect the re-routing lines 36 from etching process for the seed metal layer 35.

A second dielectric layer 38 may be provided on the first dielectric layer 34, covering the re-routing lines 36 coated with the protective coating layer 37. Parts of the second dielectric layer 38 may be removed so as to expose parts 36a of the re-routing lines 36 to the outside. The exposed parts 36a of the re-routing lines 36 may act as ball pads for the solder balls 38. Similar to the first dielectric layer 34, the second dielectric layer 38 may be made of polymeric material, such as, but not limited to polyimide, epoxy, and BCB. The second dielectric layer 38 may protect underlying elements of the WLP 30.

The solder balls 39 may be provided as package terminals on the respective ball pads 36a. An under bump metal (UBM) may be provided under the solder balls 39. It should be appreciated that other conductive connectors may be employed besides solder balls, such as, for example, bonding wires.

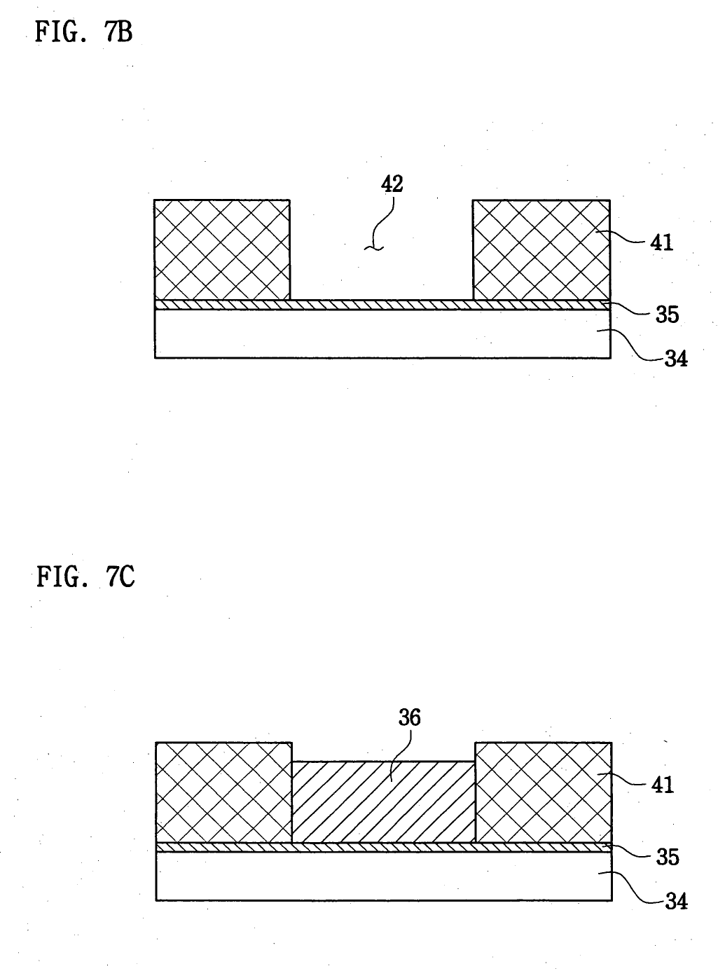

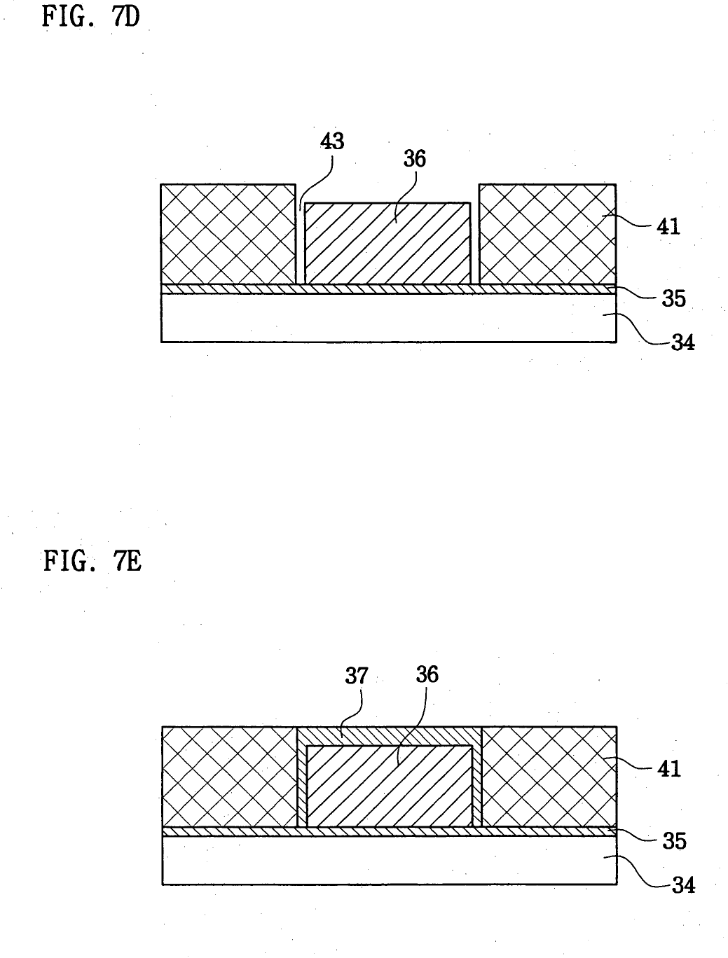

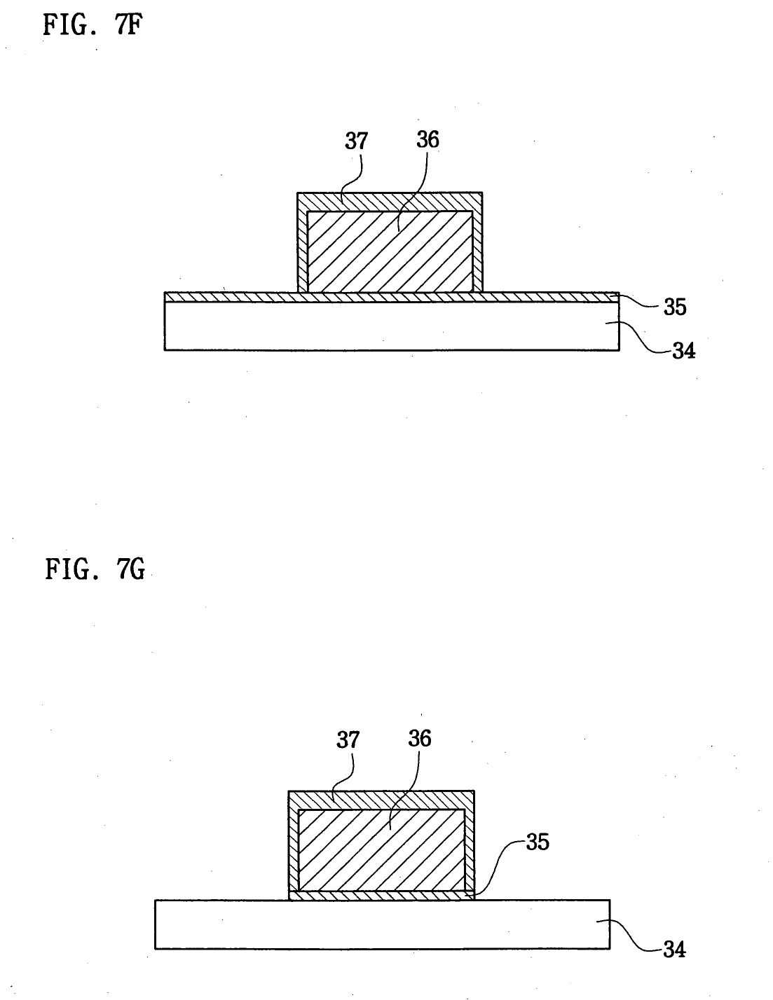

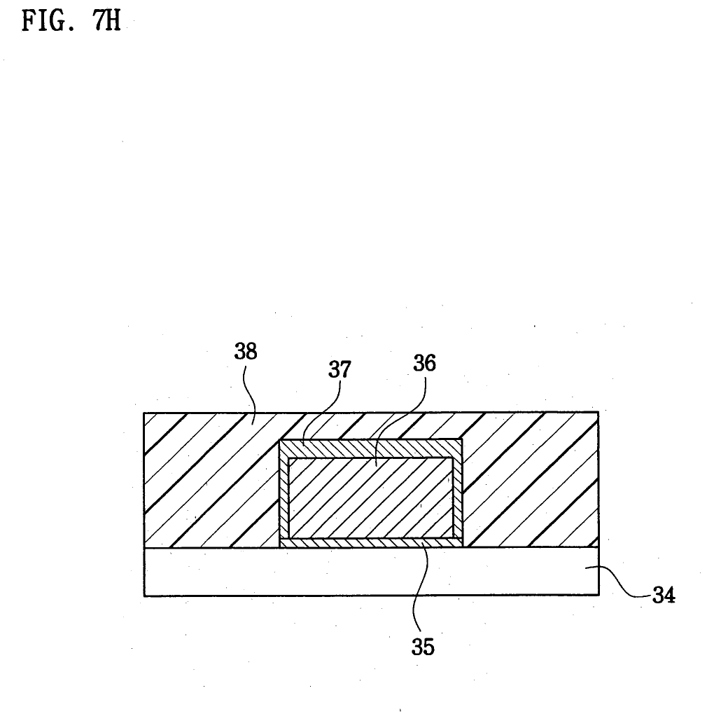

FIGS. 7A to 7H sequentially illustrate, in cross-sectional views which correspond to FIG. 6, a method of manufacturing the above-discussed exemplary embodiment of a WLP 30.

Referring to FIG. 7A, the first dielectric layer 34 may be coated on the IC chip 31 (shown in FIG. 5) by using, for example a spin coating technique. It should be appreciated that other coating techniques may be employed. The first dielectric layer 34 may be selectively removed by using, for example a photolithography technique so as to expose the I/O pads 32 (shown in FIG. 5). It should be appreciated that other techniques of removing the first dielectric layer may be employed. The seed metal layer 35 may be deposited on the first dielectric layer 34 by using, for example a sputtering technique. It should also be appreciated that other techniques of depositing the seed metal layer on the first dielectric layer may be employed.

As shown in FIG. 7B, the seed metal layer 35 may be selectively covered with a suitable photoresist pattern 41. To form the photoresist pattern 41, a photoresist layer may be coated on the seed metal layer 35, exposed, and then developed. As a result, the photoresist pattern 41 may have several openings 42 exposing selected parts of the seed metal layer 35. It should be appreciated that openings 42 may be defined generally as holes, gaps, apertures, cavities, notches, breaks and/or cracks in the photoresist pattern.

As shown in FIG. 7C, a metal layer 36a suitable for the re-routing lines 36 may be deposited on the exposed, selected part of the seed metal layer 35 within the openings 42. An electroplating technique, for example, may be used for depositing the re-routing lines 36 while using the seed metal layer 35 as a plating electrode.

After providing the re-routing lines 36, the photoresist pattern 41 may be subject to a second exposure and/or development process. Therefore, as shown in FIG. 7D, a space 43 may be produced between the photoresist pattern 41 and the re-routing lines 36. It should be appreciated that “space” may be defined differently, such as, but not limited to, gap, room, area and open region. Such second exposure process may employ positive photoresist material. In case of alternatively using negative photoresist material, the photoresist pattern 41 may be stripped and then another photoresist layer may be coated to form the space 43. It should be appreciated that more than two exposure process may be employed.

As shown in FIG. 7E, a protective coating layer 37 may be deposited on the re-routing lines 36 and in the space 43 by using, for example, an electroplating technique. It should be appreciated that other techniques may be employed to deposit the protective coating layer. As a result, the protective coating layer 37 may surround all exposed and/or uncovered surfaces (i.e., the side surfaces and the upper surface of the re-routing lines 36). The protective coating layer 37 may protect the re-routing lines 36 from subsequent etching process for the seed metal layer 35. The protective coating layer 37 may be made of various metals including, but not limited to nickel (Ni), gold (Au) and/or chromium (Cr). It will be appreciated, however, that the list of materials is presented by way of illustration only, and not as a limitation of the invention. Many suitable, alternative materials well known in the art may also be used for the protective coating layer 37. A selected material of the protective coating layer 37 may be different from a material actually used for the seed metal layer 35.

As shown in FIG. 7F, the photoresist pattern may be completely removed. The seed metal layer 35 may therefore be exposed to the outside.

As shown in FIG. 7G, the seed metal layer 35 may be subject to an etching process using the protected re-routing lines 36 as an etch mask. The etching of the seed metal layer 35 may be performed using, for example, a wet etching technique. By the etching process, exposed parts of the seed metal layer 35 may be removed so that the re-routing lines 36 may be electrically isolated from each other. Because the protective coating layer 37 may protect the re-routing lines 36 from an etching solution, sidewall over-etching or undercutting may be reduced and/or prevented in the re-routing lines 36. As discussed above, the seed metal layer 35 may be composed of several layers, so several etching solutions may be used. The material of the protective coating layer 37 may be selected according to the etching solution used.

As shown in FIG. 7H, the second dielectric layer 38 may be provided over the first dielectric layer 34, completely covering the protected re-routing lines 36. The second dielectric layer 38 may be formed using the same material and process as the first dielectric layer 34. The second dielectric layer 38 may be selectively etched to define the ball pads for the solder balls 39 (shown in FIG. 5).

As discussed above, the wafer level package according to exemplary embodiments of the present invention may be characterized by one or more protective coating layers surrounding the re-routing lines. The protective coating layer(s) may protect the re-routing lines from the etching process for the seed metal layer. The protective coating layer may be simply formed during the manufacture of the wafer level package, incurring reduced and/or no additional process and cost.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A semiconductor package, comprising:
a semiconductor chip having input/output (I/O) pads arranged on a surface thereof;
a first dielectric layer formed on the surface of the semiconductor chip, exposing the I/O pads;
a seed metal layer formed on the first dielectric layer and the I/O pads;
re-routing lines formed on the seed metal layer and electrically coupled to the I/O pads;
a protective coating layer on side surfaces and an upper surface of each re-routing line;
a second dielectric layer formed on the first dielectric layer which covers the re-routing lines surrounded with the protective coating layer, and exposes part of the re-routing lines defined as pads; and
solder balls formed on the respective pads and electrically coupled to the re-routing lines.

2. The package of claim 1, wherein the protective coating layer is made of a material different from that of the seed metal layer.

3. The package of claim 2, wherein the protective coating layer is made of metal selected from at least one of nickel (Ni), gold (Au) and chromium (Cr).

4. A semiconductor package, comprising:
a semiconductor chip having input/output (I/O) pads arranged on a surface thereof;
a first layer formed on the surface of the semiconductor chip, exposing the I/O pads;
connection lines formed on the first layer and electrically coupled to the I/O pads;
a protective coating layer on side surfaces and an upper surface of each connecting line; and
a second layer formed on the first layer which covers the connection lines surrounded with the protective coating layer.

5. The package of claim 4, wherein the I/O pads are arranged in at least one row at a central region of the semiconductor chip.

6. The package of claim 5, wherein the I/O pads are arranged in at least one row at a peripheral region of the semiconductor chip.

7. The package of claim 4, wherein the protective coating layer is made of metal selected from at least one of nickel (Ni), gold (Au) and chromium (Cr).

8. The package of claim 4, wherein the first layer is formed on a passivation layer.

9. The package of claim 4, wherein the first layer is made from a polymeric material.

10. The package of claim 9, wherein the polymeric material is at least one of a polyimide, an epoxy and a benzo-cyclo-butene.

11. The package of claim 4, wherein the second layer exposes part of the connection lines.

12. The package of claim 11, wherein the second layer is made from a polymeric material.

13. The package of claim 12, wherein the polymeric material is at least one of a polyimide, an epoxy and a benzo-cyclo-butene.

14. The package of claim 4, further comprising a seed metal layer, the seed metal layer formed on the first layer and the I/O pads.

15. The package of claim 14, wherein the connection lines are provided on the seed metal layer.

16. The package of claim 14, wherein the seed metal layer is composed of an adhesive layer and a diffusion barrier layer.

17. The package of claim 14, wherein the seed metal layer is composed of an adhesive layer, a diffusion barrier layer and a plating electrode layer.

18. The package of claim 14, wherein the seed metal layer is made from at least one metal.

19. The package of claim 18, wherein the at least one metal include at least one of titanium and copper (Ti/Cu), chromium and copper (Cr/Cu), chromium and nickel (Cr/Ni), chromium and vanadium (Cr/Ni/Au), titanium, copper and nickel (Ti/Cu/Ni), and chromium, nickel and gold (Cr/Ni/Au).

20. The package of claim 4, further comprising solder balls formed on ball pads of the second layer.

21. The package of claim 20, wherein the solder balls are provided as package terminals on the respective ball pads.

22. The package of claim 21, wherein an under bump metal is provided under the solder balls.

23. The package of claim 4, wherein the connection lines are made of copper.

24. A method of manufacturing, comprising:
forming a first dielectric layer on a semiconductor chip which includes input/output (I/O) pads arranged on a surface thereof, the first dielectric layer exposing the I/O pads;
forming a seed metal layer on the first dielectric layer and the I/O pads;
forming re-routing lines on the seed metal layer;
forming a protective coating layer on side surfaces and an upper surface of each re-routing line;
etching the seed metal layer using the re-routing lines coated with the protective coating layer as an etch mask, to remove exposed parts of the seed metal layer;
forming a second dielectric layer on the first dielectric layer so as to cover the re-routing lines coated with the protective coating layer and to expose parts of the re-routing lines defined as pads; and
forming solder balls on the respective pads.

25. The method of claim 24, wherein the protective coating layer is made of metal selected from at least one of nickel (Ni), gold (Au) and chromium (Cr).

26. The method of claim 24, wherein the etching of the seed metal layer is performed by wet etching.

27. The method of claim 24, wherein the forming of the re-routing lines includes forming a photoresist pattern having openings in the seed metal layer, and selectively depositing a metal layer on the seed metal layer within the openings.

28. The method of claim 27, wherein the photoresist pattern is formed from positive photoresist material.

29. The method of claim 27, wherein the photoresist pattern is formed from negative photoresist material.

30. The method of claim 28, wherein the forming of the protective coating layer includes forming a space between the photoresist pattern and the re-routing lines using a second exposure and development process, and selectively depositing the protective coating layer on the re-routing lines and in the space.

31. The method of claim 29, wherein the forming of the protective coating layer includes stripping the photoresist pattern, forming a second photoresist pattern having a space between the second photoresist pattern and the re-routing lines, and selectively depositing the protective coating layer on the re-routing lines and in the space.

32. The method of claim 24, wherein the forming of the protective coating layer is performed by electroplating.

33. A method of manufacturing, comprising:
forming a first layer on a semiconductor chip which includes input/output (I/O) pads arranged on a surface thereof, the first layer exposing the I/O pads;
forming connection lines on the first layer;
forming a protective coating layer on side surfaces and an upper surface of each connection line; and
forming a second layer over the first layer so as to cover the connection lines coated with the protective coating layer.

34. The method of claim 33, wherein the forming the first layer is performed by spin coating.

35. The method of claim 33, wherein the first layer exposing the I/O pads is performed by photolithography.

36. The method of claim 33, wherein the protective coating layer is made of metal selected from at least one of nickel (Ni), gold (Au) and chromium (Cr).

37. The method of claim 33, further comprising:
forming a seed metal layer on the first layer and the I/O pads; and
etching the seed metal layer while using the connection lines coated with the protective coating layer as an etch mask, to remove exposed parts of the seed metal layer.

38. The method of claim 37, wherein the seed metal layer is formed by sputtering.

39. The method of claim 37, wherein the connection lines are formed on the seed metal layer.

40. The method of claim 37, wherein the etching of the seed metal layer is performed by wet etching.

41. The method of claim 37, wherein the forming of the connection lines includes forming a photoresist pattern having openings on the seed metal layer, and selectively depositing a metal layer on the seed metal layer within the openings.

42. The method of claim 41, wherein the photoresist pattern is formed from positive photoresist material.

43. The method of claim 37, wherein the photoresist pattern is formed from negative photoresist material.

44. The method of claim 43, wherein the forming of the protective coating layer includes forming a space between the photoresist pattern and the connection lines by using a second exposure and development process, and selectively depositing the protective coating layer on the connection lines and in the space.

45. The method of claim 37, wherein the forming of the protective coating layer includes stripping the photoresist pattern, forming a second photoresist pattern having a space between the second photoresist pattern and the connection lines, and selectively depositing the protective coating layer on the connection lines and in the space.

46. The method of claim 33, wherein the forming of the protective coating layer is performed by electroplating.

47. A semiconductor package manufactured according to the method of claim 24.

48. A semiconductor package manufactured according to the method of claim 33.
